(19) United States
(12) Patent Application Publication
(10) Pub. No.: US 2026/0068326 A1
(43) Pub. Date: Mar. 5, 2026

(54) ELECTROSTATIC DISCHARGE PROTECTION DEVICE

(71) Applicant: STMicroelectronics International N.V., Geneva (CH)

(72) Inventors: Chloe Troussier, Grenoble (FR); Johan Bourgeat, Crêts en Belledonne (FR)

(21) Appl. No.: 19/283,371

(22) Filed: Jul. 29, 2025

(30) Foreign Application Priority Data
Aug. 29, 2024 (FR) 2409224

(51) Int. Cl. H10D 89/60; H10D 62/10

(52) U.S. Cl. CPC H10D 89/611; H10D 62/125

(57) ABSTRACT

The present description concerns an electronic device configured to protect an electronic component against electrostatic discharges, the electronic device comprising semiconductor regions extending in depth in a semiconductor substrate from a first surface of the semiconductor substrate, the semiconductor regions comprising a first semiconductor region of a first conductivity type, and comprising a second semiconductor region of the second conductivity type opposite to the first conductivity type, forming a PN junction with the first semiconductor region. The first semiconductor region is coupled to a first conductive track forming a first connection pin of the electronic device, the second semiconductor region is coupled to a second conductive track forming a second connection pin of the electronic device, and the semiconductor substrate is between the first conductive track and the second conductive track.

### CROSS-REFERENCE TO RELATED APPLICATIONS

This application claims the priority benefit of French patent application number 2409224, filed on Aug. 29, 2024, entitled “Dispositif de protection contre des décharges électrostatiques,” which is hereby incorporated herein by reference to the maximum extent allowable by law.

### TECHNICAL FIELD

The present disclosure generally concerns electronic devices. The present disclosure more particularly concerns devices for protecting electronic components, or integrated circuits, from electrostatic discharges.

### BACKGROUND

An unprotected integrated circuit may suffer, in case of electrostatic discharge, irreversible damage, likely to cause serious malfunctions of the integrated circuit. To overcome this disadvantage, current integrated circuits are generally equipped with electrostatic discharge protections.

### SUMMARY

There is a permanent need for higher-performance electrostatic discharge protection devices. In particular, there is a permanent need to improve the quality of electrostatic discharge protection to meet the increasing performance requirements of high-speed and high-frequency applications.

It would in particular be desirable to have electrostatic discharge protection devices which generate as little stray capacitance as possible.

An embodiment overcomes all or part of the disadvantages of known electrostatic discharge protection devices.

An embodiment provides an electronic device configured to protecting an electronic component against electrostatic discharges, the electronic device comprising semiconductor regions extending in depth in a semiconductor substrate from a first surface of the semiconductor substrate, the semiconductor regions comprising a first semiconductor region of a first conductivity type, and a second semiconductor region of the second conductivity type opposite to the first conductivity type, forming a PN junction with the first semiconductor region. The first semiconductor region is coupled to a first conductive track forming a first connection pin of the electronic device, the second semiconductor region is coupled to a second conductive track forming a second connection pin of the electronic device, and the semiconductor substrate is between the first conductive track and the second conductive track.

According to an embodiment, the semiconductor substrate has a second surface opposite to the first surface, the electronic device comprising a conductive via running through the semiconductor substrate between the first surface and the second surface, and coupling the second semiconductor region to the second conductive track.

According to an embodiment, the conductive via is insulated from the semiconductor substrate by an insulating trench.

According to an embodiment, the semiconductor regions are ring-shaped, for example concentric around each other.

According to an embodiment, the semiconductor regions are ring-shaped around the conductive via.

According to an embodiment, the first semiconductor region is a first semiconductor well and the second semiconductor region is located in the first semiconductor well, or the second semiconductor region is a first semiconductor well and the first semiconductor region is located in the first semiconductor well.

According to an embodiment, the first semiconductor region is a first semiconductor well and the second semiconductor region is a second semiconductor well in contact with the first semiconductor well.

According to an embodiment, the first and second conductive tracks are included in an interconnection structure comprising a plurality of metallization levels, including at least one first metallization level on the side of the first surface of the semiconductor substrate and at least one second metallization level on the side of the second surface of the semiconductor substrate.

According to an embodiment, the first conductive track is comprised in the first metallization level, and the second conductive track is comprised in the second metallization level.

According to an embodiment, the first conductivity type is type P, and the second conductivity type is type N.

According to an embodiment, the first conductivity type is type N, and the second conductivity type is type P.

According to an embodiment, the electronic device is an electrostatic discharge protection device comprising at least one elementary electronic component from among a diode, a bipolar transistor, a thyristor, and a triac, the at least one elementary electronic component including the semiconductor regions, the first conductive track, and the second conductive track.

An embodiment provides an integrated circuit comprising an electronic device such as described in the foregoing and an electronic component coupled to the electronic device.

According to an embodiment, the integrated circuit further comprises a first terminal coupled to the first connection pin of the electronic device and a second terminal coupled to the second connection pin of the electronic device, at least one among the first and second terminals being coupled to the electronic component.

According to an embodiment, the first and second terminals each comprise a connection pad on the side of a second surface of the semiconductor substrate opposite to the first surface, the second connection pin of the electronic device also being on the side of the second surface.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1A is a cross-section view showing an example of an electrostatic discharge protection device;

FIG. 1B is a top view showing the protection device of FIG. 1A;

FIG. 1C is a cross-section view showing an example of an integrated circuit comprising the protection device of FIG. 1A;

FIG. 2A is a cross-section view showing another example of an electrostatic discharge protection device;

FIG. 2B is a top view showing the protection device of FIG. 2A;

FIG. 3A is a cross-section view showing an electrostatic discharge protection device according to an embodiment;

FIG. 3B is a top view showing the protection device of FIG. 3A;

FIG. 3C is a cross-section view showing an example of an integrated circuit comprising an electrostatic discharge protection device according to an embodiment;

FIG. 4A is a cross-section view of an electrostatic discharge protection device according to another embodiment;

FIG. 4B is a top view showing the protection device of FIG. 4A;

FIG. 5A is a cross-section view showing an electrostatic discharge protection device according to another embodiment; and

FIG. 5B is a top view showing the protection device of FIG. 5A.

### DETAILED DESCRIPTION OF ILLUSTRATIVE EMBODIMENTS

The same elements have been designated by the same references in the various figures. Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the electronic components or the integrated circuits to be protected against electrostatic discharges are not detailed, the described embodiments being compatible with electronic components and integrated circuits conventionally protected against electrostatic discharges.

reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

In the following description, the terms “insulating” and “conductive” respectively signify, unless otherwise specified, electrically insulating and electrically conductive. This applies to the terms “insulate” and “insulated”.

In the following description, unless otherwise specified, when reference is made to a via, reference is made to a conductive via, when reference is made to a substrate, reference is made to a semiconductor substrate, when reference is made to a well, reference is made to a semiconductor well, and when reference is made to a region, reference is made to a semiconductor region.

In the following description, when reference is made to a semiconductor region, it is referred to any semiconductor region comprised in a semiconductor substrate, and a semiconductor well is considered as being a specific semiconductor region of the semiconductor substrate.

Unless otherwise specified, when reference is made to a protection device, it is referred to an electronic device intended to protect an electronic component, or an integrated circuit, against electrostatic discharges. Where there is no ambiguity, the protection device may be referred to as a “device” for short.

Throughout the disclosure, the term “ring-shaped” designates a ring shape which is represented in the drawings in a rectangular or square shape. This shape is not limiting and may be, for example, circular, oval or, more broadly, a geometric area delimited by an inner perimeter and an outer perimeter substantially parallel to each other.

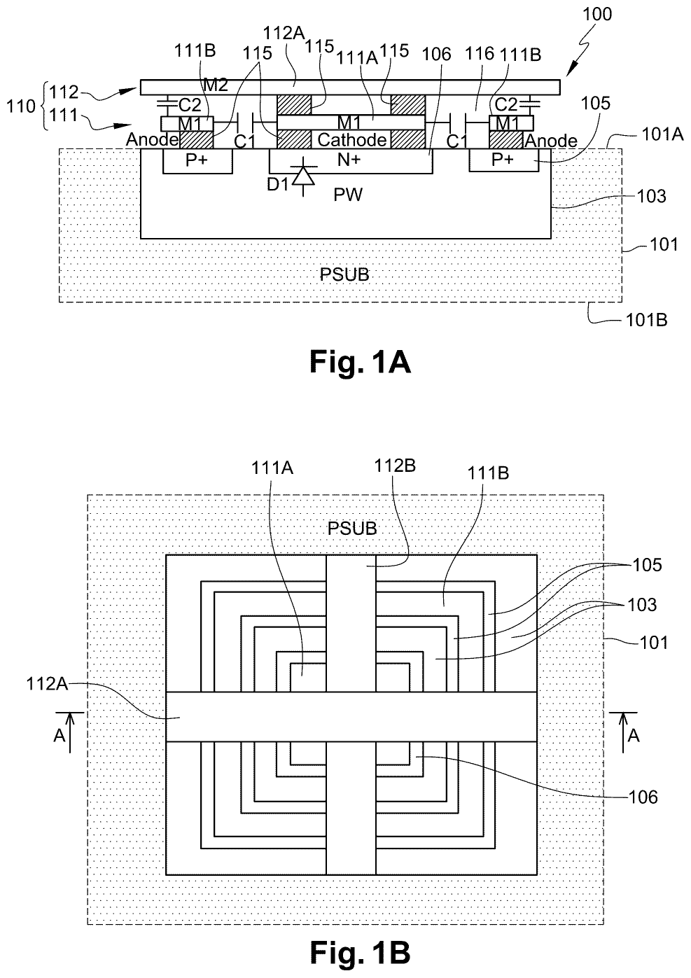

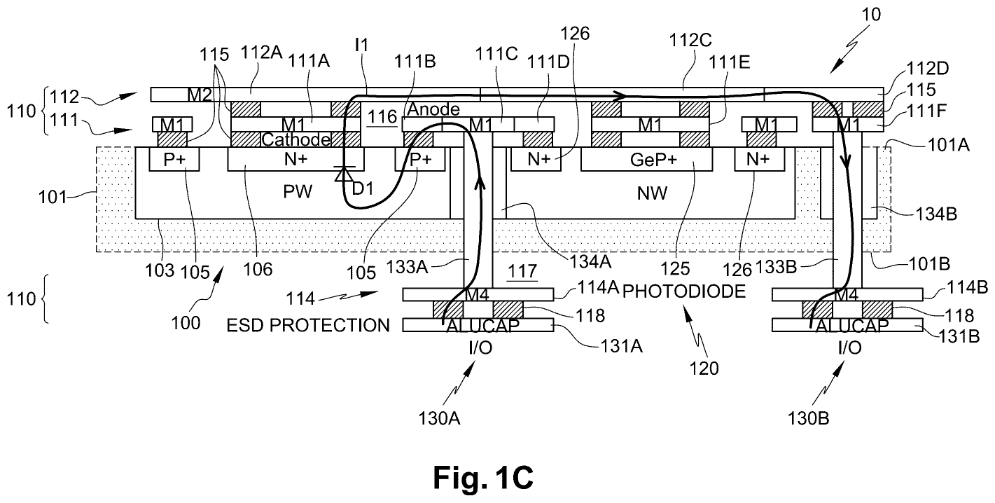

FIG. 1A is a cross-section view showing an example of an electrostatic discharge protection device 100. FIG. 1B is a top view showing the protection device 100 of FIG. 1A. FIG. 1C is a cross-section view showing an example of an integrated circuit 10 comprising the protection device 100 of FIG. 1A. FIG. 1A is a view along the cross-section plane AA shown in FIG. 1B.

In the shown example, device 100 is formed inside, and on top of, a semiconductor substrate 101 (PSUB). Substrate 101 is, for example, a wafer or a piece of wafer made of a semiconductor material, for example silicon. As an example, substrate 101 is doped with a first conductivity type, for example type P. In order not to overload the drawing, a single protection device 100 has been illustrated in FIGS. 1A and 1B, it being understood that substrate 101 may, in practice, comprise any number of protection devices 100.

As an example, semiconductor substrate 101 is of silicon-on-insulator (SOI) type. An SOI substrate typically comprises a support layer made of a semiconductor material coated with another electrically-insulating layer, for example a buried oxide (BOX) layer, itself coated with still another layer made of a semiconductor material, generally silicon.

In the shown example, protection device 100 comprises a semiconductor well 103 (PW) vertically extending into the thickness of semiconductor substrate 101 from one surface 101A of substrate 101 (the upper surface of substrate 101, in the orientation of FIG. 1A). Well 103 has a height or depth, that is, a dimension measured along a direction orthogonal to surface 101A of substrate 101, smaller than the thickness of substrate 101. In other words, well 103 does not emerge onto the side of a surface 101B of substrate 101 (the lower surface of substrate 101, in the orientation of FIG. 1A) opposite to surface 101A. The well 103 of device 100 is doped with the first conductivity type (type P, in this example) and has a higher doping level than that of substrate 101.

In the shown example, device 100 further comprises semiconductor regions 105 (P+) and 106 (N+) extending vertically across the thickness of semiconductor substrate 101 from surface 101A. Semiconductor regions 105, 106 are located in well 103 and have a depth, in well 103, much smaller than the thickness of well 103. Semiconductor regions 105, 106 are thus surrounded laterally and from below by well 103.

In the shown example, semiconductor region 106 (central semiconductor region) has, in top view, a substantially rectangular shape, and it is substantially centered with respect to the edges of well 103, and semiconductor region 105 (peripheral semiconductor region) has, in top view, substantially the shape of a ring around central semiconductor region 106.

Peripheral semiconductor region 105 is doped with the first conductivity type (type P, in this example) and has a doping level higher than that of semiconductor substrate 101 and higher than that of well 103. Central semiconductor region 106 is doped with the second conductivity type (type N, in this example) and has a doping level higher than that of semiconductor substrate 101, and higher than that of well 103, for example substantially equal to that of peripheral semiconductor region 105.

Well 103 and semiconductor regions 105, 106 are, for example, formed in substrate 101 by ion implantation from surface 101A of substrate 101.

For simplification purposes, FIGS. 1A and 1B illustrate a case in which only semiconductor regions 105 and 106, respectively doped with the first and second conductivity types, are formed in well 103. However, one or a plurality of other semiconductor regions doped with the first and/or the second conductivity type may also be formed in well 103, and/or in substrate 101 outside well 103. Further, other wells may be formed in substrate 101.

N-type semiconductor region 106 forms with P-type well 103 an NP-type heterojunction, and thus a diode D1. P-type semiconductor region 105 forms with well 103 the anode of diode D1. N-type semiconductor region 106 forms the cathode of diode D1.

Protection device 100 is coupled to conductive tracks 111, 112 forming part of a plurality of metallization levels of an interconnection structure 110. Conductive tracks 111, 112 are positioned above surface 101A of substrate 101 and all extend in a plane substantially parallel to the plane of substrate 101. Two metallization levels M1, M2 have been shown in FIG. 1A, although this is not limiting, and the number of metallization levels may be greater than two, for example. The first metallization level M1 is the metallization level closest to substrate 101, and the second metallization level M2 is a metallization level more distant from substrate 101 than the first metallization level M1.

In the shown example, the conductive tracks comprise conductive tracks 111, which are portions of a first conductive layer, for example metallic, of the first metallization level M1, and conductive tracks 112, which are portions of a second conductive layer, for example metallic, of the second metallization level M2.

Conductive tracks 111 comprise a central conductive track 111A and a peripheral conductive track 111B, which surrounds central conductive track 111A in substantially ring-shaped fashion and which is insulated from this central conductive track. Peripheral conductive track 111B may be electrically coupled to other conductive tracks 111C, 111D (shown in FIG. 1C) of the first metallization level M1, for example to couple protection device 100 to an electronic component and/or to an input/output terminal as described hereafter in relation with FIG. 1C.

Conductive tracks 112 comprise two conductive tracks 112A and 112B coupled and perpendicular to each other. This enables to have four points of connection of protection device 100 at the second metallization level M2, for example to couple protection device 100 to an electronic component and/or to an input/output terminal as described hereafter in relation with FIG. 1C.

Conductive vias 115, for example metal vias, of interconnection structure 110 couple central conductive track 111A to conductive tracks 112, as well as each of the central 111A and peripheral 111B conductive tracks to surface 101A of substrate 101.

More specifically, central conductive track 111A is coupled by vias 115 to central semiconductor region 106 on the one hand, and on the other hand by other vias 115 to conductive tracks 112, and peripheral conductive track 111B is coupled by other vias 115 to peripheral semiconductor region 105.

Conductive tracks 111 are insulated from each other and from conductive tracks 112 by an insulating layer 116, which is generally a stack of a plurality of insulating layers, separating in particular the different metallization levels and the different conductive tracks of a same metallization level. Conductive tracks 111, 112 and conductive vias 115 are embedded in insulating layer 116. Insulating layer 116 may be made of an oxide, for example a silicon oxide.

Conductive track 111B is coupled to P-type semiconductor region 105, and forms an anode electrode. Each conductive track 112 is coupled to N-type semiconductor region 106, and forms a cathode electrode. It can be observed that, due to the concentric/ring-shaped configuration of protection device 100, it is necessary to have at least two different metallization levels to connect on the one hand the cathode and on the other hand the anode while isolated from each other.

Certain electronic components, such as photodiodes, are highly sensitive to overvoltages and electrostatic discharges, and have a low robustness to overvoltages and electrostatic discharges, which requires protecting them with electrostatic discharge protection devices. The principle of a protection device is to provide a path for a discharge current so that this current does not reach the sensitive electronic component, more generally to prevent the discharge current from reaching the sensitive electronic component. Generally, a protection device is positioned close to the sensitive electronic component and/or close to an input/output terminal of this electronic component. A protection device may be similar to the protection device 100 of FIGS. 1A and 1B, but it may be any other more or less complex protection device based on diode(s), bipolar transistor(s), MOSFET transistor(s), thyristor(s), and/or triac(s) (triode for alternating current), as known to those skilled in the art. These components are referred to as elementary electronic components in the present description.

There has been shown in FIG. 1C an example of an integrated circuit 10 comprising an electronic component (PHOTODIODE), which is a photodiode 120, coupled to protection device 100 (ESD PROTECTION) via an input/output (I/O) terminal 130A. For simplification purposes, only one photodiode 120 has been shown, but the integrated circuit may comprise a plurality of photodiodes and/or a plurality of other electronic components to be protected. The ring shape of protection device 100 enables in particular to position a plurality of electronic components to be protected around this protection device.

In this example, integrated circuit 10 is of “back-side” or “back-side integrated” (BSI) type. An integrated circuit of back-side, or BSI, type designates an integrated circuit which comprises conductive tracks on the back side (below the lower surface of the substrate), that is, on the side opposite to the front side (on the upper surface of the substrate), which corresponds to the surface on top of and/or from which the electronic components are arranged. The front surface, or upper surface, can be referred to as the “front side”.

In the example shown in FIG. 1C, interconnection structure 110 comprises the conductive tracks 111, 112 described hereabove, positioned above the upper surface 101A of substrate 101, and it further comprises conductive tracks 114 of a metallization level different from the first and second levels, and on the back side, that is, under the lower surface 101B of substrate 101. Metallization level M4 has been shown, but it may be any other metallization level different from M1 and M2, for example metallization level M3. Conductive tracks 114 are portions of a conductive layer, for example metallic, of metallization level M4. Conductive tracks 114 are insulated from each other by an insulating layer 117, which is generally a stack of a plurality of insulating layers, separating on the back side (under lower surface 101B) the different metallization levels and the different conductive tracks of a same metallization level. Insulating layer 117 may be similar to insulating layer 116, for example being made of an oxide, for example a silicon oxide.

I/O terminal 130A extends on the back side, and it comprises a conductive track 114A of metallization level M4 and a connection pad 131A (ALUCAP) positioned opposite conductive track 114A and coupled thereto by conductive vias 118 of interconnection structure 110, similar to the previously-described front-side vias 115. I/O terminal 130A comprises a conductive via 133A running through substrate 101 between upper surface 101A and lower surface 101B, and coupling conductive track 114A to a conductive track 111C of the first metallization level M1 coupled to conductive track 111B. Thus, I/O terminal 130A, and its connection pad 131A, are coupled to the anode of the diode D1 of protection device 100. Conductive via 133A is insulated from all or part of substrate 101, at least from well 103, by an insulating trench 134A of STI (Shallow Trench Isolation) type.

Conductive track 111C is also coupled to an N-type doped conductive region 126 (N+) of photodiode 120 via another conductive track 111D of the first metallization level M1 coupled to conductive track 111C, enabling to couple photodiode 120 to I/O terminal 130A.

Integrated circuit 10 generally comprises a plurality of I/O terminals, for example around the periphery of integrated circuit 10.

Another I/O terminal 130B has been shown on the other side of photodiode 120 with respect to I/O terminal 130A. This I/O terminal 130B is substantially similar to I/O terminal 130A, except that it joins the second metallization level M2, is coupled to conductive track 112A, and that it is insulated from conductive tracks 111A, 111B, 111C, 111D.

I/O terminal 130B extends on the back side, and it comprises another conductive track 114B of metallization level M4, insulated from conductive track 114A. I/O terminal 130B further comprises another connection pad 131B (ALUCAP), insulated from connection pad 131A, positioned opposite conductive track 114B and coupled thereto by other conductive vias 118 of interconnection structure 110. I/O terminal 130B comprises another conductive via 133B running through substrate 101 between upper surface 101A and lower surface 101B, and coupling conductive track 114B to another conductive track 111F of the first metallization level M1 insulated from the other conductive tracks of the first metallization level M1, but coupled to another conductive track 112D of the second metallization level M2 by another via 115. Conductive track 112D is coupled to conductive track 112A via a conductive track 112C of the second metallization level M2 which is coupled to a P-type doped (GeP+) conductive region 125 of photodiode 120 via another conductive track 111E of the first metallization level M1 insulated from the other conductive tracks of the first metallization level M1. Thus, photodiode 120 is coupled to I/O terminal 130B. I/O terminal 130B, and its connection pad 131B, are thus coupled to the cathode of the diode D1 of protection device 100. Conductive via 133B is insulated from all or part of substrate 101, in this example at least along a height corresponding to the depth of well 103, by an insulating trench 134B of STI type.

It can be seen in FIG. 1C by the representation of path I1 that the current flowing from I/O terminal 130A may be deviated by protection device 100 to reach I/O terminal 130B via the second metallization level M2, to be drained off, without flowing through photodiode 120, which can thus be protected.

One or a plurality of protection devices 100 may be associated with the I/O terminals of integrated circuit 10. The I/O terminals may be intended to receive and/or to supply input/output signals, or even to receive high (V_{DD}) and low (V_{SS}) power supply potentials.

A problem with protection devices such as protection device 100 is that they introduce stray capacitances at the I/O terminals.

As can be seen in FIG. 1A, each stray capacitance is due to a conductive track/insulating layer/conductive track junction. Stray capacitances C1 are formed at the first metallization level M1, in this example between central conductive track 111A and peripheral conductive track 111B. Other stray capacitances C2 are formed between the first and second metallization levels M1 and M2, in this example between the peripheral conductive track 111B and each conductive track 112.

However, certain applications, for example photodetection or photonics applications, are highly sensitive to stray capacitance. This is particularly critical in HF (High Frequency) applications, typically in electronic devices such as photosensors which comprise photodiodes. For example, stray capacitances may degrade the signals exchanged between the electronic device and the outside via the I/O terminals.

Thus, in these applications, it may be desirable to minimize the stray capacitances of protection devices, in order to maintain the functionality of the I/O terminals and the desired performance of the electronic components coupled to these I/O terminals, or comprising these I/O terminals.

To decrease the impact of the metallization, that is, of the conductive tracks in the insulating layer, it may be attempted to increase the distances between the conductive tracks of the protection device, without degrading its robustness.

A common solution consists in enlarging the size of a protection device to increase the space between conductive tracks. However, in the case of a ring-shaped/concentric protection device such as previously described, this may considerably increase the size of the protection device.

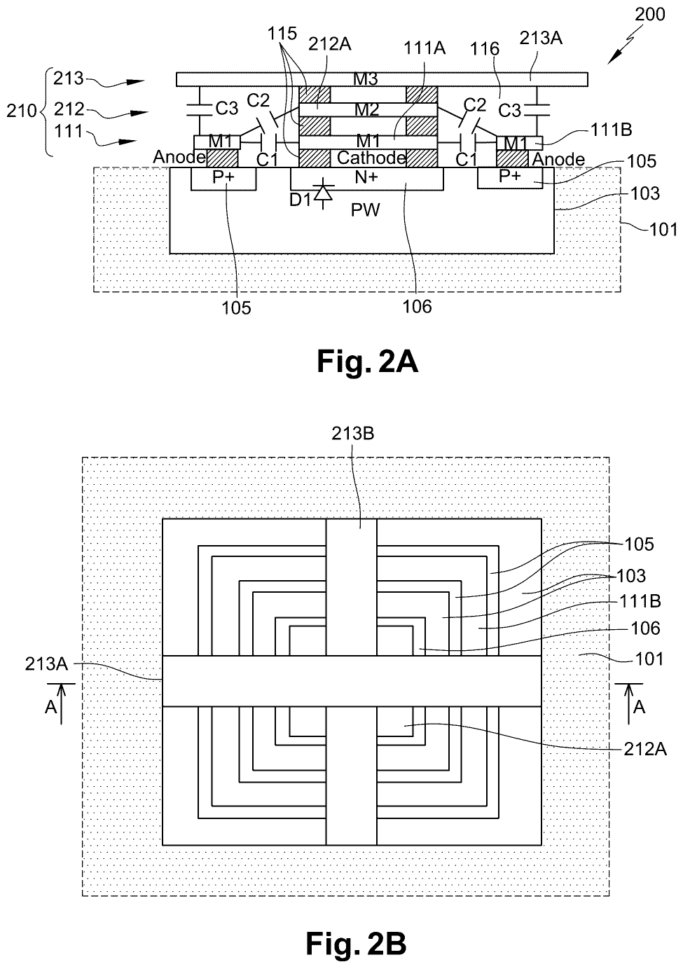

Another solution comprises adding another metallization level on the front side, as illustrated hereafter in relation with FIGS. 2A and 2B.

FIG. 2A is a cross-section view showing another example of an electrostatic discharge protection device 200. FIG. 2B is a top view showing the protection device 200 of FIG. 2A. FIG. 2A is a view along the cross-section plane AA shown in FIG. 2B.

The protection device 200 of FIGS. 2A and 2B comprises elements in common with the protection device 100 of FIGS. 1A and 1B. These common elements will not be described again hereafter.

The device 200 of FIGS. 2A and 2B differs from the device 100 of FIGS. 1A and 1B in that interconnection structure 210 comprises a conductive track 212A of the second metallization level M2, which faces, does not extend on either side of, central conductive track 111A, and in particular does not extend above peripheral conductive track 111B. Conductive track 212A is coupled to N-type semiconductor region 106, and thus to the cathode of diode D1, via central conductive track 111A and conductive vias 115. The cathode interconnection is performed at a third metallization level M3 by conductive tracks 213, which are coupled to conductive track 212A by conductive vias 115, and thus to N-type semiconductor region 106. Conductive tracks 213 comprise two conductive tracks 213A and 213B coupled and perpendicular to each other.

This configuration enables to decrease the stray capacitances C2 between the first and second metallization levels M1 and M2, due to a greater distance between peripheral conductive track 111B and conductive track 212A. The stray capacitances C3 between conductive track 111B and each conductive track 213 are decreased, since each conductive track 213 is formed at a third metallization level M3 higher than the second metallization level M2, thus increasing the distance between conductive tracks 111B and 213.

However, in this configuration, stray capacitances are not removed between the different metallization levels. Further, thus takes up metallization portions that cannot be used for another connection.

There thus exists a need for an electrostatic discharge protection device which generates as little stray capacitance as possible, without for all this increasing the size of the protection device, and without degrading its performance. In particular, there exists a need not to degrade, or even to improve, the quality of protection devices in the high-speed and high-frequency fields.

It would be desirable for the electrostatic discharge protection device not require adding, or taking up, one or a plurality of metallization levels, or one or a plurality of conductive tracks.

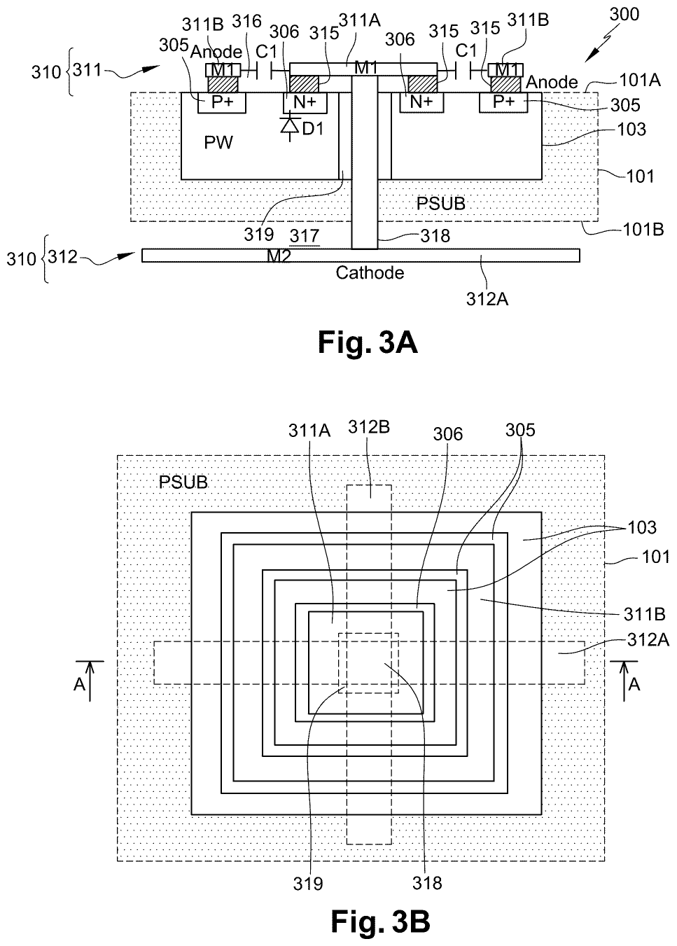

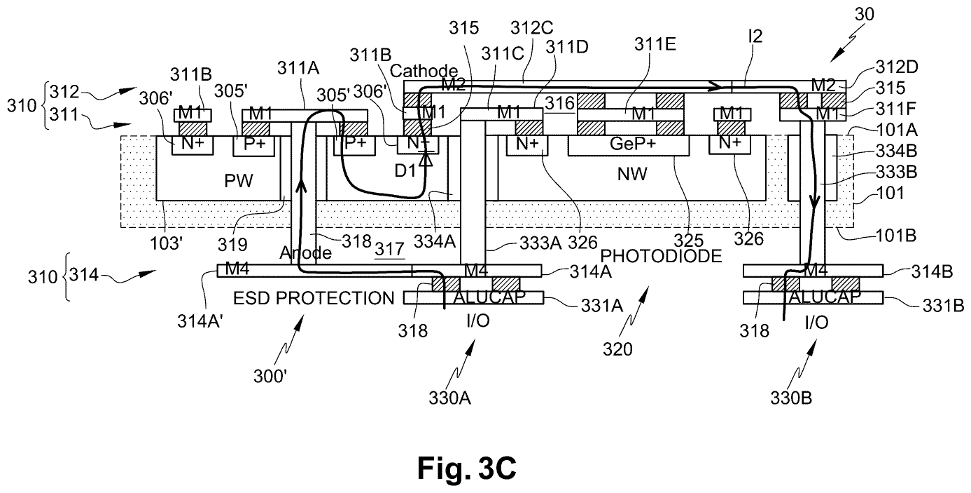

FIG. 3A is a cross-section view showing an electrostatic discharge protection device 300 according to an embodiment. FIG. 3B is a top view showing the protection device 300 of FIG. 3A. FIG. 3A is a view along the cross-section plane AA shown in FIG. 3B.

The protection device 300 of FIGS. 3A and 3B has elements in common with the protection device 100 of FIGS. 1A and 1B. These common elements will not be described again hereafter.

The protection device 300 of FIGS. 3A and 3B differs from the protection device 100 of FIGS. 1A and 1B in that the anode and cathode interconnections are not formed on the same surface of semiconductor substrate 101. In the example of FIGS. 3A and 3B, the anode is interconnected above the upper surface 101A of substrate 101 (front side), and the cathode is interconnected below the lower surface 101B of substrate 101 (back side). In other words, the anode and the cathode are interconnected on either side of substrate 101. The back side interconnection of the cathode comprises a conductive via 318 running through substrate 101 between the upper surface 101A and the lower surface 101B. Conductive via 318 is insulated from all or part of substrate 101, at least from well 103, by an insulating trench 319 of STI type. As will be seen in the example in FIG. 3C, as a variant, the anode could be interconnected on the front side and the cathode on the back side. Conductive via 318 and insulating trench 319 are shown in dotted lines and in transparency in FIG. 3B, being below central conductive track 311A.

Advantage is taken of back-side integrated (BSI) technology to interconnect the electrodes of protection device 300, while moving away from each other the conductive tracks forming these electrodes, as explained hereafter, so as to decrease the stray capacitances that they could generate.

The protection device 300 of FIGS. 3A and 3B comprises a semiconductor well 103 (PW), similar to the semiconductor well 103 of FIGS. 1A and 1B. This well extends vertically across a partial thickness of semiconductor substrate 101 from a surface 101A of substrate 101. Well 103 is doped with the first conductivity type (type P, in this example) and has a doping level higher than that of substrate 101.

Device 300 further comprises semiconductor regions, a semiconductor region 305 (P+), and a semiconductor region 306 (N+), extending vertically into the thickness of semiconductor substrate 101 from surface 101A. Semiconductor regions 305 and 306 are located in well 103, and have a depth in well 103 much lower than the thickness of well 103. Semiconductor regions 305, 306 are thus surrounded laterally and from below by well 103. Semiconductor region 305 is doped with the first conductivity type (type P, in this example) and has a doping level higher than that of semiconductor substrate 101 and higher than that of well 103. Semiconductor region 306 is doped with the second conductivity type (type N, in this example) and has a doping level higher than that of semiconductor substrate 101 and higher than that of well 103, for example substantially equal to that of semiconductor region 305.

N-type semiconductor region 306 forms with P-type well 103 an NP-type heterojunction, and thus a diode D1. P-type semiconductor region 305 forms the anode of diode D1. N-type semiconductor region 306 forms, with well 103, the cathode of diode D1.

In the example shown in FIGS. 3A and 3B, N-type semiconductor region 306 is a central semiconductor region which has, in top view, substantially the shape of a ring around insulating trench 319. The semiconductor region 306 of FIGS. 3A and 3B thus differs from the semiconductor region 106 of FIGS. 1A and 1B in that it is ring-shaped, and not rectangular. This enables to have conductive via 318 run through substrate 101, with insulating trench 319 around it. P-type semiconductor region 305 is a peripheral semiconductor region, and has, in top view, substantially the shape of a ring around N-type semiconductor region 306, similarly to the semiconductor region 105 of FIGS. 1A and 1B.

Well 103 and semiconductor regions 305, 306, are for example, formed in substrate 101 by ion implantation from surface 101A of substrate 101.

In the example shown in FIGS. 3A and 3B, interconnection structure 310 comprises conductive tracks 311 of a metallization level M1, similar to the conductive tracks 111 previously described in relation with FIGS. 1A and 1B, positioned above the upper surface 101A of substrate 101, and conductive tracks 312 of a metallization level different from metallization level M1, below the lower surface 101B of substrate 101: metallization level M2 has been shown, but it may be any other metallization level different from M1, for example metallization level M3 or M4.

Conductive tracks 311 comprise a central conductive track 311A and a peripheral conductive track 311B which surrounds in substantially ring-shaped fashion central conductive track 311A and which is insulated from this central conductive track by an insulating layer 316 of interconnection structure 310. Peripheral conductive track 311B and/or central conductive track 311A could be electrically coupled to other conductive tracks (not shown) of metallization level M1 and/or of another metallization level, for example to couple protection device 300 to an electronic component and/or to an input/output terminal.

In FIG. 3B, conductive tracks 312 are shown in dotted lines and in transparency, being under substrate 101. They comprise two conductive tracks 312A and 312B coupled and perpendicular to each other, for example to couple protection device 300 to an electronic component and/or to an input/output terminal, as described hereafter in relation with FIG. 3C.

Central conductive track 311A is coupled to conductive tracks 312 by conductive via 318.

The conductive tracks 311 of metallization level M1 are insulated from each other and from substrate 101 by insulating layer 316, which may be similar to the insulating layer 116 of FIGS. 1A and 1B. Insulating layer 316 separates on the front side (on upper surface 310A) the different metallization levels and the different conductive tracks of the same metallization level. Insulating layer 316 is generally a stack of a plurality of insulating layers. Insulating layer 316 may be made of an oxide, for example a silicon oxide.

The conductive tracks 312 of metallization level M2 are insulated from each other and from substrate 101 by an insulating layer 317, which may be similar to insulating layer 316. Insulating layer 317 separates on the back side (under lower surface 101B) the different metallization levels and the different conductive tracks of the same metallization level. Insulating layer 317 is generally a stack of a plurality of insulating layers. Insulating layer 317 may be made of an oxide, for example, a silicon oxide.

Conductive track 311B is coupled to P-type semiconductor region 305, and forms an anode electrode. Each conductive track 312 is coupled to the N-type semiconductor region 106, and forms a cathode electrode.

As can be seen in FIG. 3A, the stray capacitances C2 of FIG. 1A, which were formed between the first and second metallization levels M1 and M2, between the anode electrode and the cathode electrode of FIG. 1A, could have been removed, and this, without adding an additional metallization level, and without increasing the size of the protection device. In the device of FIGS. 3A and 3B, anode electrode 311B and cathode electrode 311A are spaced apart from each other since they are on either side of substrate 101.

The Inventors have determined that for N-type semiconductor region 306 to be ring-shaped to give way to conductive via 318, and not rectangular, would not disturb the flowing of current, since the current flows preferentially at the periphery of the N-type semiconductor region, and to a lesser extent at the center of the N-type semiconductor region. Thus, the performance of the protection device is not degraded, even in high-speed and high-frequency applications.

Further, in an integrated circuit in back-side technology, one already has a metallization level, and thus conductive tracks, under the lower surface of the substrate, in addition, generally, to conductive tracks on the upper surface of the substrate. The protection device can thus be easily formed by using a standard method of back-side type, or even by being inserted in the integrated circuit manufacturing method.

FIG. 3C is a cross-section view showing an example of an integrated circuit 30 comprising a protection device 300′ according to an embodiment. There has been shown in FIG. 3C an example of an integrated circuit 30 comprising an electronic component (PHOTODIODE), which is a photodiode 320, similar to the photodiode 120 of FIG. 1C, coupled to protection device 300′ (ESD PROTECTION) via an input/output (I/O) terminal 330A. For simplification purposes, only one photodiode 320 is shown, but integrated circuit 30 may comprise a plurality of photodiodes and/or one or a plurality of other electronic components to be protected. The ring shape of protection device 300, 300′ enables in particular to position a plurality of electronic components to be protected around this protection device.

The protection device 300′ of FIG. 3C is similar to that of FIGS. 3A and 3B, except that in well 103′ PW, the anode-forming P-type semiconductor region 305′ is a central, and no longer peripheral, semiconductor region, and the cathode-forming N-type semiconductor region 306′ is a peripheral, and no longer central, semiconductor region. Thus, central conductive track 311A is in this case coupled to the anode, and no longer to the cathode, and thus forms the anode electrode. Similarly, peripheral conductive track 311B is coupled to the cathode, and no longer to the anode, and thus forms the cathode electrode. Those skilled in the art will be capable of configuring the connections described in the following for a protection device similar to the device 300 of FIGS. 3A and 3B.

Similarly to FIG. 1C, I/O terminal 330A comprises a back-side connection pad 331A (ALUCAP), positioned opposite a conductive track 314A at metallization level M4, also on the back side. Conductive track 314A is coupled to connection pad 331A by conductive vias 318 of interconnection structure 310, similar to the front-side vias 315 described hereabove. I/O terminal 330A comprises a conductive via 333A running through substrate 101 between upper surface 101A and lower surface 101B, and coupling conductive track 314A to a conductive track 311C of metallization level M1 insulated from conductive track 311B. Conductive via 333A is insulated from all or part of substrate 101, at least from well 103′, by an insulating trench 334A of STI type. Conductive track 314A is further coupled on the back side to a conductive track 314A′, which forms the anode connection of the diode D1 of protection device 300′. Conductive track 314A′ is coupled to central conductive track 311A by conductive via 318.

In FIG. 3C, metallization level M4 has been shown on the back side, instead of the metallization level M2 of FIGS. 3A and 3B, metallization level M2 being on the front side in FIG. 3C. Thus, reference 312A has been replaced with reference 314A′. One may not have metallization level M2 on the front side, for example, only metallization level M1.

Thus, I/O terminal 330A and its connection pad 331A are coupled to the anode of the diode D1 of protection device 300′ via conductive track 314A′.

Conductive track 311C is also coupled to an N-type doped conductive region 326 (N+) of photodiode 120 via another conductive track 311D of metallization level M1, enabling to couple photodiode 320 to I/O terminal 330A.

Another I/O terminal 330B has been shown on the other side of photodiode 320 with respect to I/O terminal 330A. This I/O terminal 330B is substantially similar to I/O terminal 330A, except that it joins metallization level M2.

I/O terminal 330B comprises another conductive track 314B of metallization level M4, insulated from conductive track 314A. I/O terminal 330B comprises another connection pad 331B (ALUCAP), insulated from connection pad 331A, positioned opposite conductive track 314B and coupled thereto by other conductive vias 318 of interconnection structure 310. I/O terminal 330B further comprises another conductive via 333B running through substrate 101 between upper surface 101A and lower surface 101B. Conductive via 333B is insulated from all or part of substrate 101, in this case at least along a height corresponding to the depth of well 103′, by another insulating trench 334B of STI type. Conductive via 333B couples conductive track 314B to another conductive track 311F of metallization level M1, insulated from the other conductive tracks of metallization level M1, but coupled to a conductive track 312D of metallization level M2 by other vias 315. Conductive track 312D is coupled to another conductive track 312C of metallization level M2, which is coupled to a P-type doped (GeP+) conductive region 325 of photodiode 320 via another conductive track 311E of metallization level M1 insulated from the other conductive tracks of metallization level M1. Thus, photodiode 320 is coupled to I/O terminal 330B. Conductive track 312C is coupled by other vias 315 to peripheral conductive track 311B, which forms the cathode electrode. Thus, I/O terminal 330B, and its connection pad 331B, are coupled to the cathode of the diode D1 of protection device 300.

There can be seen in FIG. 3C by a representation of the path of current 12 that the current flowing from terminal I/O 330A can be deviated by protection device 300 to reach terminal I/O 330B via metallization level M2 so as to be drained off, without flowing through photodiode 320, which can thus be protected.

Further, it can be understood from FIG. 3C that protection device 300′ may be simply connected to I/O terminal 330A, since the conductive track 314A′ of protection device 300′ is on the back side, like the connection pad 331A (ALUCAP) and the conductive track 314A of I/O terminal 330A, and is further at the same metallization level M4 as the conductive track 314A of I/O terminal 330A. Protection device 300′ can thus for example be located as close as possible to I/O terminal 330A, which enables to optimize the protection.

One or a plurality of protection devices 300 may be associated with the I/O terminals of integrated circuit 30. The I/O terminals may be intended to receive and/or to supply input/output signals, or even to receive high (VDD) and low (VSS) power supply potentials.

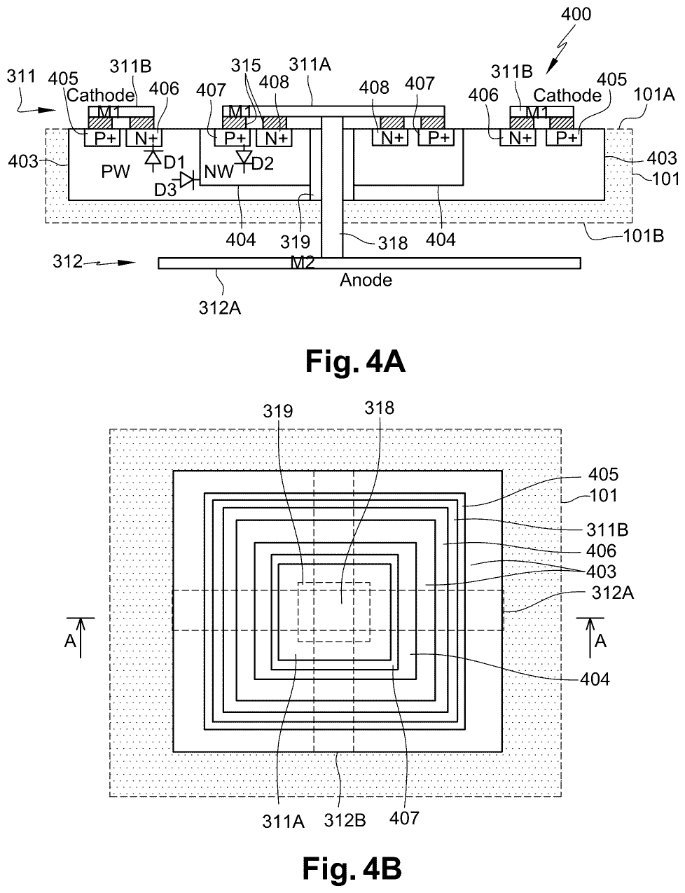

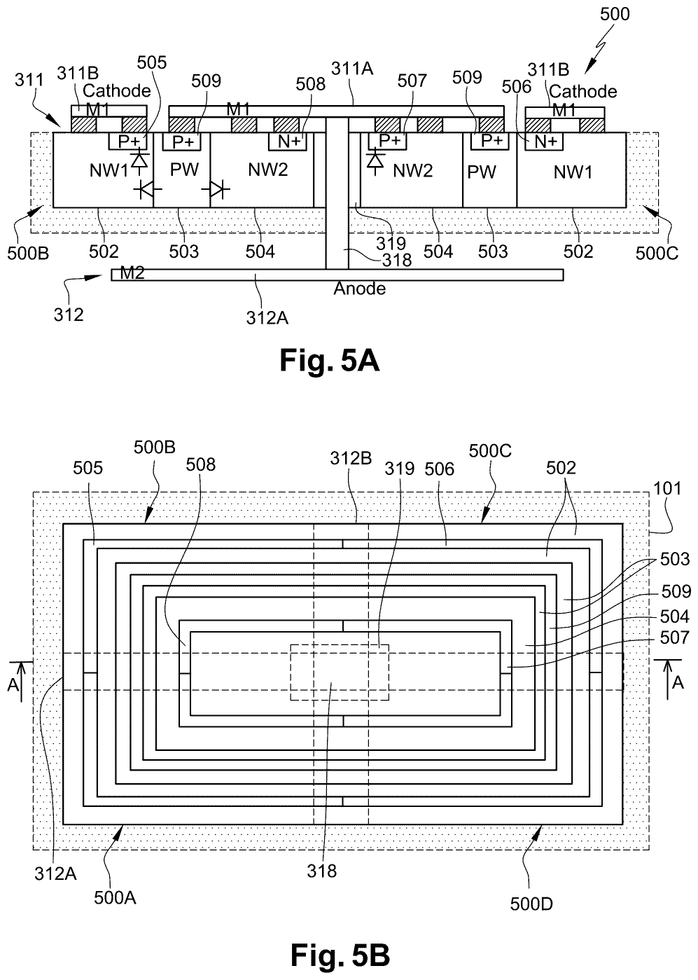

FIG. 3C shows an example of an integrated circuit 30 comprising a protection device 300′ similar to that of FIGS. 3A and 3B, but this is not limiting and the protection device of the integrated circuit could be any electronic device of the embodiments, for example any of the protection devices 400, 500 of FIGS. 4A, 4B and 5A, 5B.

The electronic component to be protected is preferably formed in/on the same substrate as the protection device.

The integrated circuit is preferably not three-dimensional (3D), that is, it preferably does not result from a stacking of several chips. The integrated circuit is preferably a two-dimensional (2D) integrated circuit, that is, an integrated circuit made of a single chip.

Although protection devices 300, 300′ are based on a diode, a protection device according to an embodiment may be based on a plurality of diodes, on bipolar and/or MOSFET transistor(s), on thyristor(s), on triac(s), or on a combination of a plurality of these electronic components, in a way known to those skilled in the art. Two other types of protection devices will be illustrated in the following in relation with FIGS. 4A, 4B, 5A, and 5B, although these examples are not limiting.

The interconnection structure 310 of FIGS. 4A, 4B, 5A, and 5B is similar to that of FIGS. 3A and 3B. It comprises in particular conductive tracks 311 of metallization level M1, as well as vias 315 and an insulating layer 316, on the front side. Interconnection structure 310 further comprises conductive tracks 312 of metallization level M2, as well as an insulating layer 317, on the back side. Similarly to what has been described in relation with FIGS. 3A and 3B, conductive tracks 311 comprise a central conductive track 311A and a peripheral conductive track 311B which surrounds in substantially ring-shaped fashion central conductive track 311A, and conductive tracks 312 comprise two conductive tracks 312A and 312B coupled and perpendicular to each other. Conductive tracks 312 are shown in dotted lines and in transparency in FIGS. 4B and 5B, being under substrate 101.

FIG. 4A is a cross-section view showing an electrostatic discharge protection device 400 according to another embodiment. FIG. 4B is a top view showing the protection device 400 of FIG. 4A. FIG. 4A is a view along the cross-section plane AA shown in FIG. 4B.

The protection device 400 of FIGS. 4A and 4B has elements in common with the protection device 300 of FIGS. 3A and 3B. These common elements will not be described again hereafter.

The protection device 400 of FIGS. 4A and 4B differs from the protection device 300 of FIGS. 3A and 3B in that it is of thyristor type. For short, protection device 400 may be referred to as a thyristor in the following description.

The protection device 400 of FIGS. 4A and 4B comprises:
a semiconductor well 403 (PW), extending vertically into the thickness of semiconductor substrate 101 from the upper surface 101A of substrate 101, and having a height smaller than the thickness of substrate 101; and
a semiconductor well 404 (NW), extending vertically into the thickness of semiconductor substrate 101 from the upper surface 101A of substrate 101, and having a height smaller than the thickness of substrate 101.

Well 403 is of the first conductivity type, in this example type P. Well 404 is of the second conductivity type, in the example type N. Wells 403 and 404 are in contact, forming a PN junction.

Wells 403 and 404 have a doping level higher than that of semiconductor substrate 101. As an example, well 403 has a doping level substantially equal to that of well 404.

In the example of FIGS. 4A and 4B, well 404 is ring-shaped around conductive via 318 and insulating trench 319, shown in dotted lines and in transparency in FIG. 4A, being under conductive track 311A. Well 403 is also ring shaped and it surrounds well 404.

A semiconductor region 405 of the first conductivity type, in the example type P, and a semiconductor region 406 of the second conductivity type, in the example type N, are located in well 403. Regions 405 and 406 extend vertically into the thickness of semiconductor substrate 101 from the upper surface 101A, their thicknesses being much smaller than those of substrate 101 and of well 403. Semiconductor regions 405 and 406 have a doping level higher than that of semiconductor substrate 101 and of well 403.

A semiconductor region 407 of the first conductivity type, in the example type P, and a semiconductor region 408 of the second conductivity type, in the example type N, are located in well 404. Regions 407 and 408 extend vertically into the thickness of semiconductor substrate 101 from upper surface 101A, their thicknesses being much smaller than those of substrate 101 and of well 404. Semiconductor regions 407 and 408 have a doping level higher than that of semiconductor substrate 101 and of well 404.

In the example shown in FIGS. 4A and 4B, semiconductor regions 405, 406, 407, 408 each have, in top view, a ring shape around conductive via 318 and insulating trench 319. Semiconductor region 408 is the closest to conductive via 318 and insulating trench 319. Semiconductor region 407 is arranged around semiconductor region 408. Semiconductor region 406 is arranged around semiconductor region 407. Semiconductor region 405 is arranged around semiconductor region 406.

The configuration of FIGS. 4A and 4B is non-limiting and, for example, P-type semiconductor region 407 could be the closest to conductive via 318 and to insulating trench 319, N-type semiconductor region 408 could be around P-type semiconductor region 407, P-type semiconductor region 405 could be around N-type semiconductor region 408, and N-type semiconductor region 406 could be around P-type semiconductor region 405. A thyristor structure with a central P-type well and a peripheral N-type well could also be envisaged. Those skilled in the art will be capable of envisaging any other configuration, as long as it enables to form a thyristor, more generally with a P+ region and an N+ region in a PW well, as well as an N+ region and a P+ region in an NW well.

N-type semiconductor region 406 forms with P-type well 403 an NP-type heterojunction, and thus a first diode D1. P-type semiconductor region 407 forms with N-type well 404 a PN-type heterojunction, and thus a second diode D2, reversed with respect to the first diode D1. Thyristor 400 thus comprises the first diode D1 and the second diode D2 reversed with respect to the first diode D1. Further, the PN heterojunction between well 403 and well 404 forms a third diode D3.

Thyristor 400 can also be represented by two nested bipolar transistors: a first PNP transistor which comprises the junctions formed by P+ region 407, NW well 404, and PW well 403 (the N+ region 408 in NW well 404 forming a control for this first transistor), and a second NPN transistor which comprises the junctions formed by N+ region 406, PW well 403, and NW well 404 (the P+ 405 region in PW well 403 forming a control for this second transistor).

In the example shown in FIGS. 4A and 4B, thyristor 400 comprises a first gate, or control electrode, corresponding to the P-type region 405 located in P-type well 403, and a second gate corresponding to the N-type region 408 located in N-type well 404. In this example, the first and second gates 405 and 408 are respectively connected to peripheral conductive track 311B and to central conductive track 311A, which respectively form the cathode and anode of thyristor 400. In other words, the gate 405 and the cathode 311B of thyristor 400 are short-circuited. Similarly, the gate 408 and the anode 311A of thyristor 400 are short-circuited. The anode 311A of thyristor 400 is coupled to conductive track 312 on the back side by conductive via 318. Thyristor 400 is in this case in the off mode and is equivalent to a diode comprising a PN heterojunction having its doped region of the second conductivity type (type N, in this example) formed by semiconductor regions 407 and 408 and by well 404, and having its doped region of the first conductivity type (type P, in this example) formed by regions 405 and 406 and by well 403. Electrodes 311A and 311B respectively correspond, for the diode to which thyristor 400 is equivalent in off mode, to cathode and anode electrodes, while they respectively correspond to the anode and to the cathode of thyristor 400. The current can flow between region 407 and region 406.

The turn-on voltage of the thyristor, such as that shown in FIGS. 4A and 4B, is different from that of the diode-based protection device, such as that shown in FIGS. 3A and 3B.

This example of a thyristor is not limiting, and other thyristor structures can be envisaged by those skilled in the art. For example, one of the gates, or both gates, may not be short-circuited with the thyristor anode or cathode. This enables to control the triggering of the protection and to trigger it at lower voltages.

FIG. 5A is a cross-section view showing an electrostatic discharge protection device 500 according to another embodiment. FIG. 5B is a top view showing the protection device 500 of FIG. 5A. In FIG. 5B, metallization level M1 has not been shown to better visualize the semiconductor regions and the semiconductor wells. FIG. 5A is a view along the cross-section plane AA shown in FIG. 5B, with the addition of metallization level M1.

The protection device 500 of FIGS. 5A and 5B comprises elements in common with the protection device 300 of FIGS. 3A and 3B. These common elements will not be described again hereafter.

The protection device 500 of FIGS. 5A and 5B differs from the protection device 300 of FIGS. 3A and 3B in that it is of triac type. For short, protection device 500 may be referred to as a triac in the following description. A triac can be seen as an elementary electronic component equivalent to the arranging in parallel of two thyristors, such as the thyristor 400 of FIGS. 4A and 4B, mounted head-to-tail (the anode of one is coupled to the cathode of the other, the respective gates being controlled simultaneously).

The protection device 500 of FIGS. 5A and 5B comprises a semiconductor well 502 (NW1), extending vertically into the thickness of semiconductor substrate 101 from the upper surface 101A of substrate 101, and having a height smaller than the thickness of substrate 101, a semiconductor well 503 (PW), extending vertically into the thickness of semiconductor substrate 101 from the upper surface 101A of substrate 101, and having a height smaller than the thickness of substrate 101, and a semiconductor well 504 (NW2), extending vertically into the thickness of semiconductor substrate 101 from the upper surface 101A of substrate 101, and having a height smaller than the thickness of substrate 101.

In the example of FIGS. 5A and 5B, well 504 is in the shape of a ring around conductive via 318 and insulating trench 319, shown in dotted lines and in transparency in FIG. 5B, being under conductive track 311A. Well 503 is also ring-shaped and it surrounds well 504, while being in contact with well 504. Well 502 is also ring-shaped and surrounds well 503, being in contact with well 503.

Well 502 is of the second conductivity type, in the example, type N. Well 503 is of the first conductivity type, in the example, type P. Well 504 is of the second conductivity type, in the example, type N.

Wells 502, 503, and 504 have a doping level higher than that of semiconductor substrate 101. As an example, well 502 has a doping level substantially equal to that of well 504. As an example, wells 502 and 504 have a doping level substantially equal to that of well 503.

In top view, thyristor 500 is organized in four portions 500A, 500B, 500C, 500D of equal size. Portions 500A and 500C are symmetrical with respect to the center and are similar. Portions 500B and 500D are symmetrical with respect to the center and are similar.

In portions 500A and 500C, a semiconductor region 506 of the second conductivity type, in the example type N, is located in well 502. In portions 500B and 500D, a semiconductor region 505 of the first conductivity type, in the example type P, is located in well 502. Regions 505 and 506 extend vertically into the thickness of semiconductor substrate 101 from upper surface 101A, their thicknesses being much smaller than those of substrate 101 and of well 502. Semiconductor regions 505 and 506 have a doping level higher than that of semiconductor substrate 101 and of well 502. Regions 505 and 506 are coupled together in well 502 and form a continuous ring.

In portions 500B and 500D, a semiconductor region 508 of the second conductivity type, in the example type N, is located in well 504. In portions 500A and 500C, a semiconductor region 507 of the first conductivity type, in the example type P, is located in well 504. Regions 507 and 508 extend vertically into the thickness of semiconductor substrate 101 from upper surface 101A, their thicknesses being much smaller than those of substrate 101 and of well 504. Semiconductor regions 507 and 508 have a doping level higher than that of semiconductor substrate 101 and of well 504. Regions 507 and 508 are coupled together in well 504 and form a continuous ring.

In the four portions 500A, 500B, 500C, 500D, a semiconductor region 509 of the first conductivity type, in the example type P, is located in P-type well 503. Region 509 extends vertically into the thickness of semiconductor substrate 101 from upper surface 101A, its thickness being much smaller than those of substrate 101 and of well 503. Semiconductor region 509 has a doping level higher than that of semiconductor substrate 101 and of well 503. Region 509 is ring-shaped.

In the example shown in FIGS. 5A and 5B, semiconductor regions 507 and 508 coupled together have, in top view, a ring shape around conductive via 318 and insulating trench 319, semiconductor region 509 has, in top view, a ring shape around semiconductor regions 507 and 508, and the semiconductor regions 505 and 506 coupled together have, in top view, a ring shape around semiconductor region 509.

P-type semiconductor region 505 forms a PN-type heterojunction with N-type well 502, and thus a first diode. P-type semiconductor region 507 forms a PN-type heterojunction with N-type well 504, and thus a second diode, in the same direction as the first diode. The heterojunctions between PW well 503 and each of the NW wells 502, 504 form two diodes in reverse directions.

In the example shown in FIGS. 5A and 5B, triac 500 comprises a gate, or control electrode, corresponding to the P-type semiconductor region 509 located in P-type well 503.

In the example of FIGS. 5A and 5B, gate 509 is coupled to central conductive track 311A, which forms the anode of triac 500 and which is also coupled to regions 507 and 508. In other words, the gate 509 and the anode 311A of triac 500 are short-circuited. The anode 311A of triac 500 is coupled to the conductive tracks 312 on the back side by conductive via 318. Regions 505 and 506 are coupled to each other and to peripheral conductive track 311B, which forms the cathode of triac 500. As compared with diode or thyristor protection devices, such as those previously described, the triac provides a bidirectional structure, where the current can flow from the anode to the cathode of the triac, and from the cathode to the anode of the triac.

This example of a triac is not limiting, and other triac structures can be envisaged by those skilled in the art. For example, it can be envisaged to have a P-type ring-shaped region and an N-type ring-shaped region in each of the N-type wells 502 and 504. The four portions 500A, 500B, 500C, 500D of triac 500 would then be similar. A triac structure with two P-type wells, each including an N-type ring-shaped region and a P-type ring-shaped region, and one N-type well, including an N+ ring-shaped region, between these two P-type wells, can also be envisaged.

The embodiments described hereabove can be used in many types of industrial markets, for example, the personal electronics industry, for example in the field of mobile telephony and of the Internet of Things (IoT), as well as in the field of high-speed interfaces, or the industry of communications equipment, computers and peripherals, for example in the field of infrastructures and data centers.

For example, the embodiments described hereabove can be used in many applications implementing fiber communication.

Various embodiments and variants have been described. Those skilled in the art will understand that certain features of these various embodiments and variants could be combined, and other variants will become apparent to those skilled in the art. In particular, although the case where the first conductivity type is P and the second conductivity type is N has been detailed hereabove, the described embodiments and variants are transposable by those skilled in the art to the case where the first conductivity type is N and the second conductivity type is P.

Further, although the semiconductor wells and the semiconductor regions of the protection devices previously described in relation with FIGS. 3A, 3B, 4A, 4B, 5A, and 5B each have a ring shape in top view, the semiconductor wells and the semiconductor regions of the protection devices could as a variant each have a different shape. As an example, the semiconductor wells and the semiconductor regions of the protection devices could each have, in top view, the shape of a strip extending laterally along a direction orthogonal to the cross-section plane of FIGS. 3A, 4A, and 5A, or of an elongated “U” extending laterally along a direction orthogonal to the cross-section plane of FIGS. 3A, 4A, and 5A, that is, an open ring shape.

Further, although there has been shown in FIGS. 1C and 3C a photodiode as the electronic component to be protected, it may be any electronic component which is desired to be protected from electrostatic discharges.

Finally, the practical implementation of the described embodiments and variants is within the abilities of those skilled in the art, based on the functional indications given hereabove. In particular, those skilled in the art are capable of predicting the values of the doping levels of the semiconductor substrate, of the N-doped semiconductor wells, of the P-doped semiconductor wells, as well as of the N-doped semiconductor regions and of the P-doped semiconductor regions.

What is claimed is:

1. An electronic device for protecting an electronic component against electrostatic discharges, the electronic device comprising:
semiconductor regions extending in depth in a semiconductor substrate from a first surface of the semiconductor substrate, the semiconductor regions comprising:
a first semiconductor region of a first conductivity type; and
a second semiconductor region of a second conductivity type opposite to the first conductivity type, forming a PN junction with the first semiconductor region;
wherein the first semiconductor region is coupled to a first conductive track forming a first connection pin of the electronic device, the second semiconductor region is coupled to a second conductive track forming a second connection pin of the electronic device, and the semiconductor substrate is between the first conductive track and the second conductive track.

2. The electronic device according to claim 1, wherein the semiconductor substrate has a second surface opposite to the first surface, the electronic device comprising a conductive via running through the semiconductor substrate between the first surface and the second surface, and coupling the second semiconductor region to the second conductive track.

3. The electronic device according to claim 2, wherein the conductive via is insulated from the semiconductor substrate by an insulating trench.

4. The electronic device according to claim 2, wherein the semiconductor regions are ring-shaped.

5. The electronic device according to claim 4, wherein the semiconductor regions are concentric.

6. The electronic device according to claim 4, wherein the semiconductor regions are ring-shaped around the conductive via.

7. The electronic device according to claim 1, wherein the first semiconductor region is a first semiconductor well and the second semiconductor region is located in the first semiconductor well, or the second semiconductor region is a second semiconductor well and the first semiconductor region is located in the second semiconductor well.

8. The electronic device according to claim 1, wherein the first semiconductor region is a first semiconductor well and the second semiconductor region is a second semiconductor well in contact with the first semiconductor well.

9. The electronic device according to claim 2, wherein the first and second conductive tracks are included in an interconnection structure comprising a plurality of metallization levels, including at least one first metallization level on the first surface of the semiconductor substrate and at least one second metallization level on the second surface of the semiconductor substrate.

10. The electronic device according to claim 9, wherein the first conductive track is disposed in the first metallization level, and the second conductive track is disposed in the second metallization level.

11. The electronic device according to claim 1, wherein the first conductivity type is type P, and the second conductivity type is type N.

12. The electronic device according to claim 1, wherein the first conductivity type is type N, and the second conductivity type is type P.

13. The electronic device according to claim 1, wherein the electronic device is an electrostatic discharge protection device comprising at least one elementary electronic component selected from the group consisting of a diode, a bipolar transistor, a thyristor, or a triac, and wherein the at least one elementary electronic component includes the semiconductor regions, the first conductive track, and the second conductive track.

14. The electronic device according to claim 1, wherein the electronic component is disposed in and/or on the same semiconductor substrate as the electronic device.

15. An integrated circuit comprising:
an electronic device comprising semiconductor regions extending in depth in a semiconductor substrate from a first surface of the semiconductor substrate, the semiconductor regions comprising:
a first semiconductor region of a first conductivity type; and
a second semiconductor region of a second conductivity type opposite to the first conductivity type, forming a PN junction with the first semiconductor region;
wherein the first semiconductor region is coupled to a first conductive track forming a first connection pin of the electronic device, the second semiconductor region is coupled to a second conductive track forming a second connection pin of the electronic device, and the semiconductor substrate is between the first conductive track and the second conductive track; and
an electronic component coupled to the electronic device.

16. The integrated circuit according to claim 15, further comprising:
a first terminal coupled to the first connection pin of the electronic device; and
a second terminal coupled to the second connection pin of the electronic device;
wherein at least one of the first and second terminals is coupled to the electronic component.

17. The integrated circuit according to claim 16, wherein the first and second terminals each comprise a connection pad on a second surface of the semiconductor substrate opposite to the first surface, wherein the second connection pin of the electronic device is on the second surface.

18. The integrated circuit according to claim 15, wherein the semiconductor substrate has a second surface opposite to the first surface, the electronic device comprising a conductive via running through the semiconductor substrate between the first surface and the second surface, and coupling the second semiconductor region to the second conductive track.

19. The integrated circuit according to claim 15, wherein the first semiconductor region is a first semiconductor well and the second semiconductor region is located in the first semiconductor well, or the second semiconductor region is a second semiconductor well and the first semiconductor region is located in the second semiconductor well.

20. The integrated circuit according to claim 15, wherein the first semiconductor region is a first semiconductor well and the second semiconductor region is a second semiconductor well in contact with the first semiconductor well.

21. The integrated circuit according to claim 15, wherein the first conductivity type is type P, and the second conductivity type is type N.

22. The integrated circuit according to claim 15, wherein the integrated circuit is a two-dimensional (2D) integrated circuit.
